(19) United States
(12) Patent Application Publication
(10) Pub. No.: US 2024/0047234 A1
(43) Pub. Date: Feb. 8, 2024

(54) SUBSTRATE PROCESSING APPARATUS, SUPPLY SYSTEM, SUBSTRATE PROCESSING METHOD, AND SUPPLY METHOD

(71) Applicant: Tokyo Electron Limited, Tokyo (JP)

(72) Inventors: Yosuke HACHIYA, Kumamoto (JP); Itaru KANNO, Kumamoto (JP); Mitsunori NAKAMORI, Kumamoto (JP); Hirofumi TAKEGUCHI, Kumamoto (JP)

(21) Appl. No.: 18/227,156

(22) Filed: Jul. 27, 2023

(30) Foreign Application Priority Data
Aug. 2, 2022 (JP) 2022-123165
Mar. 23, 2023 (JP) 2023-046156

(51) Int. Cl. H01L 21/67; B08B 3/14; H01L 21/02

(52) U.S. Cl. CPC H01L 21/67023; B08B 3/14; H01L 21/02057

(57) ABSTRACT

A substrate processing apparatus includes: a holding unit, a processing cup, a first supply unit, a second supply unit, a drain unit, and a first measurement unit. The holding unit holds a substrate. The processing cup is provided around the holding unit. The first supply unit supplies a chemical liquid to the substrate held by the holding unit. The second supply unit supplies a rinse liquid or a drying liquid to the substrate held by the holding unit. The drain unit is provided at the bottom of the processing cup, and is connected to a drain line and a recovery line via a line switch. The first measurement unit is provided in the drain unit, and measures the purity of the rinse liquid or the drying liquid.

### CROSS-REFERENCE TO RELATED APPLICATIONS

This application is based on and claims priority from Japanese Patent Application Nos. 2022-123165 and 2023-046156, filed on Aug. 2, 2022 and Mar. 23, 2023, respectively, with the Japan Patent Office, the disclosures of which are incorporated herein in their entireties by reference.

### TECHNICAL FIELD

The present disclosure relates to a substrate processing apparatus, a supply system, a substrate processing method, and a supply method.

### BACKGROUND

Japanese Laid-Open Patent Publication No. 2000-294531 discloses a single-wafer chemical processing apparatus, which performs a chemical liquid processing and a pure water processing, while adopting a technique of separating a drain system for the chemical liquid processing and a drain system for the pure water processing, thereby implementing an efficient drainage and recovery.

### SUMMARY

According to an aspect of the present disclosure, a substrate processing apparatus includes: a holding unit, a processing cup, a first supply unit, a second supply unit, a drain unit, and a first measurement unit. The holding unit holds a substrate. The processing cup is provided around the holding unit. The first supply unit supplies a chemical liquid to the substrate held by the holding unit. The second supply unit supplies a rinse liquid or a drying liquid to the substrate held by the holding unit. The drain unit is provided at the bottom of the processing cup, and is connected to a drain line and a recovery line via a line switch. The first measurement unit is provided in the drain unit, and measures the purity of the rinse liquid or the drying liquid.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating a schematic configuration of a substrate processing system according to a first embodiment.

FIG. 2 is a schematic view illustrating an example of a specific configuration of a processing unit according to the first embodiment.

FIG. 3 is a flow chart illustrating an example of a procedure of a control process performed by the substrate processing system according to the first embodiment.

FIG. 4 is a flow chart illustrating an example of a procedure of a pure water recovering process performed by the substrate processing system according to the first embodiment.

FIG. 5 is a flow chart illustrating another example of the procedure of the pure water recovering process performed by the substrate processing system according to the first embodiment.

FIG. 6 is a block diagram illustrating an example of a configuration of a pure water supply system according to the first embodiment.

FIG. 7 is a schematic view illustrating an example of a specific configuration of a processing unit according to a modification of the first embodiment.

FIG. 8 is a view illustrating a schematic configuration of a substrate processing system according to a modification of the first embodiment.

FIG. 9 is a schematic block diagram illustrating an example of a configuration of a supply system according to a second embodiment.

FIG. 10 is a schematic view illustrating an example of a specific configuration of a processing unit according to the second embodiment.

FIG. 11 is a flow chart illustrating an example of a procedure of a control process performed by the supply system according to the second embodiment.

FIG. 12 is a schematic view illustrating an example of a specific configuration of a processing unit according to a third embodiment.

FIG. 13 is a flow chart illustrating an example of a procedure of a drying liquid recovering process performed by a substrate processing system according to the third embodiment.

FIG. 14 is a flow chart illustrating another example of the procedure of the drying liquid recovering process performed by the substrate processing system according to the third embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing a substrate processing apparatus, a supply system, a substrate processing method, and a supply method according to the present disclosure (hereinafter, referred to as “embodiments”) will be described in detail with reference to the drawings. The present disclosure is not limited by the embodiments. Further, the embodiments may be appropriately combined with each other within the scope that does not cause any inconsistency in process contents. In the respective embodiments, the same components will be denoted by the same reference numerals, and overlapping descriptions will be omitted.

In the embodiments described herein below, terms such as “constant,” “orthogonal,” “perpendicular,” and “parallel” may be used, not requiring being strictly “constant,” “orthogonal,” “perpendicular,” and “parallel.” That is, the terms may each allow a deviation in, for example, manufacture accuracy and installation accuracy.

In each drawing to be referred-to herein below, an orthogonal coordinate system may be represented, in which an X-axis direction, a Y-axis direction, and a Z-axis direction are defined to be orthogonal to each other, and the Z-axis positive direction is a vertically upward direction, in order to facilitate the understanding of descriptions. Further, the direction of a rotation around a vertical axis may be referred to as the θ direction.

Japanese Laid-Open Patent Publication No. 2000-294531 discloses a single-wafer chemical processing apparatus, which performs a chemical liquid processing and a pure water processing, adopting a technique of separating a drain system for the chemical liquid processing and a drain system for the pure water processing, thereby implementing the efficient drainage and recovery. However, in the method disclosed in the publication above, a low-purity rinsing or drying liquid, into which the chemical liquid adhering to a substrate is mixed, may be recovered, which requires a further improvement.

Therefore, a technology of recovering a high-purity rinsing or drying liquid is expected.

### First Embodiment

### Outline of Substrate Processing System

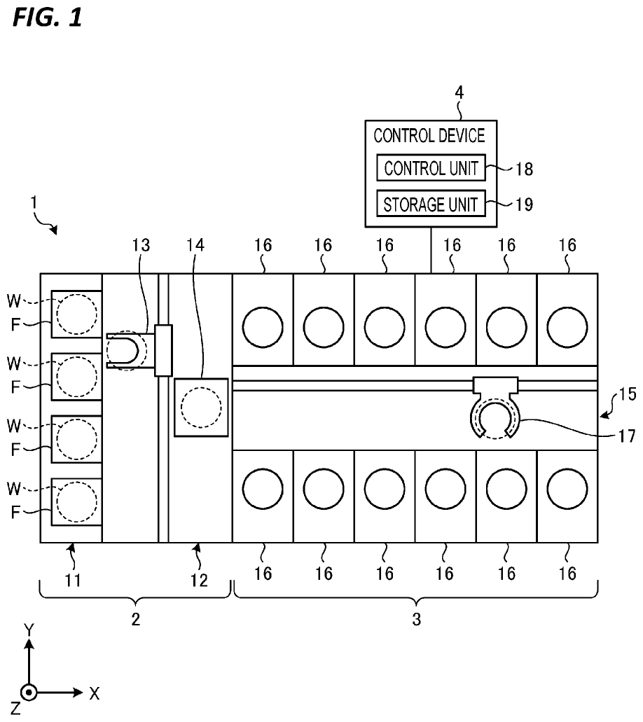

First, a schematic configuration of a substrate processing system 1 according to a first embodiment will be described with reference to FIG. 1. FIG. 1 is a view illustrating the schematic configuration of the substrate processing system 1 according to the first embodiment. The substrate processing system 1 is an example of a substrate processing apparatus.

As illustrated in FIG. 1, the substrate processing system 1 includes a carry-in/out station 2 and a processing station 3. The carry-in/out station 2 and the processing station 3 are provided adjacent to each other.

The carry-in/out station 2 includes a front opening unified pod (FOUP) arrangement section 11 and a transfer section 12. In the FOUP arrangement section 11, a plurality of FOUPs F is arranged to each accommodate a plurality of substrates, i.e., semiconductor wafers W in the first embodiment (hereinafter, referred to as “wafers W”), in a horizontal state.

The transfer section 12 is provided adjacent to the FOUP arrangement section 11, and includes a substrate transfer device 13 and a delivery unit 14 therein. The substrate transfer device 13 includes a wafer holding mechanism that holds the wafer W. The substrate transfer device 13 is movable horizontally and vertically while being pivotable around a vertical axis, and transfers the wafer W between the FOUP F and the delivery unit 14 by using the wafer holding mechanism.

The processing station 3 is provided adjacent to the transfer section 12. The processing station 3 includes a transfer section 15 and a plurality of processing units 16. The plurality of processing units 16 are arranged at both sides of the transfer section 15.

The transfer section 15 includes a substrate transfer device 17 therein. The substrate transfer device 17 includes a wafer holding mechanism that holds the wafer W. The substrate transfer device 17 is movable horizontally and vertically while being pivotable around a vertical axis, and transfers the wafer W between the delivery unit 14 and the processing units 16 by using the wafer holding mechanism.

The processing units 16 each perform a predetermined substrate processing on the wafer W transferred by the substrate transfer device 17.

The substrate processing system 1 further includes a control device 4. The control device 4 is, for example, a computer, and includes a control unit 18 and a storage unit 19. The storage unit 19 stores programs for controlling various processes executed in the substrate processing system 1. The control unit 18 reads and executes the programs stored in the storage unit 19, to control the operation of the substrate processing system 1.

The programs may be recorded in a computer-readable recording medium, and installed from the recording medium into the storage unit 19 of the control device 4. The computer-readable recording medium may be, for example, a hard disk (HD), a flexible disk (FD), a compact disk (CD), a magnet optical (MO) disk, or a memory card.

In the substrate processing system 1 configured as described above, the substrate transfer device 13 of the carry-in/out station 2 first takes out the wafer W from the FOUP F disposed in the FOUP arrangement section 11, and disposes the taken wafer W on the delivery unit 14. The wafer W disposed on the delivery unit 14 is taken out from the delivery unit 14 by the substrate transfer device 17 of the processing station 3, and carried into a processing unit 16.

The wafer W carried into the processing unit 16 is processed with a liquid by the processing unit 16, and then, carried out from the processing unit 16 and disposed on the delivery unit 14 by the substrate transfer device 17. The processed wafer W that has been disposed on the delivery unit 14 returns to the FOUP F of the FOUP arrangement section 11 by the substrate transfer device 13.

### Configuration of Processing Unit

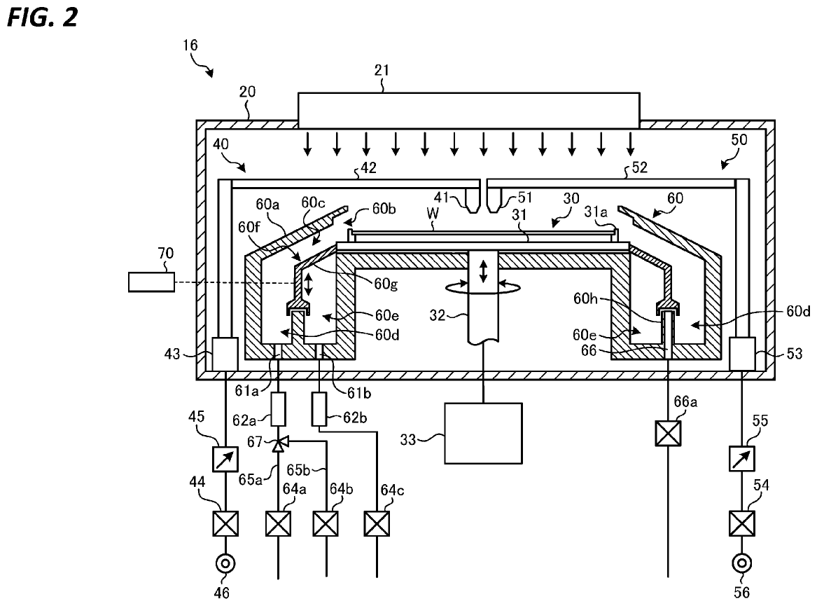

Next, a configuration of the processing unit 16 according to the first embodiment will be described with reference to FIG. 2. FIG. 2 is a schematic view illustrating an example of the specific configuration of the processing unit 16 according to the first embodiment. As illustrated in FIG. 2, the processing unit 16 includes a chamber 20, a substrate processing unit 30, a first supply unit 50, a second supply unit 50, and a recovery cup 60.

While FIG. 2 illustrates the recovery cup 60 configured with two multi-tiered cups, the number of cups is not limited to two. This configuration will be described later.

The chamber 20 accommodates the substrate processing unit 30, the first supply unit 50, the second supply unit 50, and the recovery cup 60. A fan filter unit (FFU) 21 is provided at the ceiling of the chamber 20. The FFU 21 forms a downflow inside the chamber 20.

The substrate processing unit 30 includes a holding unit 31, a support column 32, and a drive unit 33, and performs a liquid processing on the disposed wafer W. The holding unit 31 holds the wafer W horizontally. The support column 32 is a vertically extending member, of which lower end is rotatably supported by the drive unit 33 and of which upper end supports the holding unit 31 horizontally. The drive unit 33 rotates the support column 32 around the vertical axis.

The substrate processing unit 30 rotates the support column 32 by using the drive unit 33 to rotate the holding unit 31 supported on the support column 32, thereby rotating the wafer W held in the holding unit 31.

A holding member 31a is provided on the top surface of the holding unit 31 of the substrate processing unit 30, to hold the wafer W from side. The holding member 31a holds the wafer W horizontally in a state of being slightly spaced apart from the top surface of the holding unit 31.

The first supply unit 40 supplies a chemical liquid onto the wafer W held by the holding unit 31. The first supply unit 40 includes a nozzle 41, an arm 42 that supports the nozzle 41 horizontally, and a swivel/lift mechanism 43 that swivels and moves up/down the arm 42.

The nozzle 41 is connected to a chemical liquid supply source 46 via a valve 44 and a flow rate regulator 45. The chemical liquid supply source 46 is a tank that stores a chemical liquid. As for the chemical liquid, for example, HF (hydrofluoric acid), HF/HNO₃ (nitrohydrofluoric acid), HF/HNO₃/CH₃COOH (hydrofluoric acid-nitric acid-acetic acid mixed acid), SCl (ammonia-hydrogen peroxide mixed solution), and TMAH (tetramethylammonium hydroxide) may be used.

A thin film (e.g., an oxide film, a nitride film, or a silicon film), which may be etched by, for example, the chemical liquid described above, is formed on the front surface of the wafer W.

The second supply unit 50 supplies a rinse liquid to the wafer W held by the holding unit 31 to perform a rinsing process on the wafer W. The rinse liquid is, for example, pure water. The pure water is, for example, deionized water (DIW). The second supply unit 50 includes a nozzle 51, an arm 52 that supports the nozzle 51 horizontally, and a swivel/lift mechanism 53 that swivels and moves up/down the arm 52.

The nozzle 51 is connected to a DIW supply source 56 via a valve 54 and a flow rate regulator 55. The DIW supply source 56 is a tank that stores DIW.

The recovery cup 60 (an example of a processing cup) is disposed around the holding unit 31, and collects a liquid scattered from the wafer W due to the rotation of the holding unit 31. The recovery cup 60 may be configured with multi-tiered cups arranged concentrically with the rotation center of the wafer W rotating while being held by the substrate processing unit 30. Specifically, the recovery cup 60 includes a pure water recovery cup 60a (an example of a second processing cup) and a drain recovery cup 60f (an example of a first processing cup).

The pure water recovery cup 60a has a shape that surrounds the portion below the wafer W and the outside of the outer periphery of the wafer W and opens the portion above the wafer W. The pure water recovery cup 60a is provided outside the drain recovery cup 60f. The pure water recovery cup 60a forms a recovery port 60b outside the outer periphery of the wafer W, and forms a recovery space 60c below the wafer W to communicate with the recovery port 60b.

Further, the pure water recovery cup 60a forms a concentric ring-shaped partition wall 60h at the bottom of the recovery space 60c, to divide the bottom of the recovery space 60c into a pure water recovery section 60d and a drain section 60e that have a concentric double-ring shape. The pure water recovery section 60d is disposed outside the drain section 60e. In the bottom of the recovery space 60c, the bottom portion where the pure water recovery section 60d is disposed is an example of the “bottom of the second processing cup.” In the bottom of the recovery space 60c, the bottom portion where the drain section 60e is disposed is an example of the “bottom of the first processing cup.”

A drain port 61a is formed in the pure water recovery section 60d. The discharge path from the drain port 61a is connected to a drain line 65a and a recovery line via a switch valve 67 (an example of a line switch). For example, when the control device 4 controls the switch valve 67 to set the drain line 65a as the inflow destination of a drain liquid, the drain liquid discharged from the drain port 61a flows into the drain line 65a through a valve 64a. Similarly, for example, when the control device 4 controls the switch valve 67 to set the recovery line 65b as the inflow destination of a drain liquid, the drain liquid discharged from the drain port 61a flows into the recovery line 65b through a valve 64b.

The pure water recovery section 60d is provided with a measurement unit 62a (an example of a first measurement unit) that measures the purity of the pure water. The “purity of the pure water” herein refers to the proportion of water (H₂O), which is a main component, in the pure water. The “high purity of the pure water” indicates that the proportion of water (H₂O) as the main component is high, in other words, the proportion of components (impurities) other than the main component is low. The purity of the pure water may be estimated from, for example, the conductivity, concentration, specific resistance, pH, and total organic carbon (TOC) of the pure water. Thus, for example, a conductivity meter, a concentration meter, a specific resistance meter, a pH meter, or a TOC meter may be used as the measurement unit 62a. The specific resistance is a reciprocal number of the conductivity.

A drain port 61b is formed in the drain section 60e. The discharge path from the drain port 61b is connected to a valve 64c. The drain liquid discharged from the drain port 61b is discharged to the outside of the processing unit 16 through the valve 64c. The valve 64c may be configured with a plurality of separate valves according to the property of the chemical liquid such as acidity or alkalinity to branch the discharge path to correspond to the valves, respectively. When the chemical liquid is reusable, the chemical liquid discharged through the valve 64c may be recovered.

The drain section 60e is provided with a drain measurement unit 62b (an example of a second measurement unit) that measures the purity of the pure water. The drain measurement unit 62b is, for example, a conductivity meter, a density meter, or a specific resistance meter.

In the partition wall 60h of the pure water recovery cup 60a, a plurality of exhaust ports 66 is formed at intervals along the circumferential direction of the partition wall 60h, to penetrate the partition wall 60h and be opened above the drain ports 61a and 61b in the recovery cup 60. The discharge path from each exhaust port 66 is connected to a valve 66a.

The drain recovery cup 60f is disposed directly above the partition wall 60h at a predetermined interval, and is provided to be movable up and down. A lift mechanism (an example of a cup switch) is connected to the drain recovery cup 60f to move the drain recovery cup 60f up and down. The control unit 4 controls the lift mechanism 70 to move up and down.

At the upper end of the drain recovery cup 60f, a slope wall 60g is provided to slope inwardly upward up to the recovery port 60b of the pure water recovery cup 60a. The slope wall 60g extends in parallel to the slope wall of the pure water recovery cup αa up to the recovery port 60b of the pure water recovery cup 60a, while being close to the slope wall of the pure water recovery cup 60a.

When the drain recovery cup 60f is moved down using the lift mechanism 70, a flow path is formed between the slope wall of the pure water recovery cup 60a and the slope wall 60g of the drain recovery cup 60f inside the recovery space 60c, to extend from the recovery port 60b to the drain port 61a.

When the drain recovery cup 60f is moved up using the lift mechanism 70, a flow path is formed inside the slope wall 60g of the drain recovery cup 60f to extend from the recovery port 60b to the drain port 61b of the drain section 60e.

When performing the substrate processing, the processing unit 16 switches the drain ports 61a and 61b by moving the drain recovery cup 60f up and down.

For example, when the wafer W is processed by ejecting the chemical liquid onto the wafer W, the control device 4 controls the drive unit 33 of the substrate processing unit 30 to rotate the holding unit 31 at a predetermined rotation speed, and opens the valve 44. Then, the chemical liquid supplied from the chemical liquid supply source 46 is ejected from the nozzle 41 onto the upper surface of the wafer W.

At this time, the control device 4 controls the lift mechanism 70 to move up the drain recovery cup 60f, thereby forming the flow path extending from the recovery port 60b to the drain port 61b of the drain section 60e.

As a result, the chemical liquid supplied onto the wafer W is expelled toward the outside of the outer periphery of the wafer W due to the centrifugal force caused by the rotation of the wafer W, and is recovered into the drain section 60e from the recovery port 60b. Then, the chemical liquid is discharged from the drain port 61b. In other words, the state where the drain recovery cup 60f moves up indicates the state where the drain recovery cup 60f receives the liquid (hereinafter, also referred to as a first state).

For example, when the wafer W is processed by ejecting the pure water onto the wafer W, the control device 4 similarly controls the drive unit 33 to rotate the holding unit 31 at a predetermined rotation speed, and opens the valve 54. Then, the DIW supplied from the DIW supply source 56 is ejected from the nozzle 51 onto the upper surface of the wafer W.

At this time, the control device 4 controls the lift mechanism 70 to move down the drain recovery cup 60f, thereby forming the flow path extending from the recovery port 60b to the drain port 61a of the pure water recovery section 60d.

As a result, the pure water supplied onto the wafer W is expelled toward the outside of the outer periphery of the wafer W due to the centrifugal force by the rotation of the wafer W, and is recovered into the pure water recovery section 60d of the recovery space 60c from the recovery port 60b of the pure water recovery cup 60a. Then, the pure water is discharged from the drain port 61a. In other words, the state where the drain recovery cup 60f moves down indicates the state where the pure water recovery cup 60a receives the liquid (hereinafter, also referred to as a second state).

The switch of the drain ports 61a and 61b performed by moving the drain recovery cup 60f up and down may be referred to as a “cup switch.”

### Procedure of Control Process

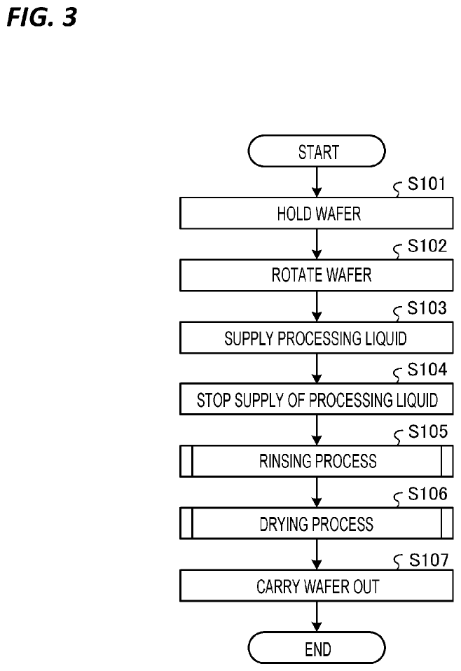

Next, the procedure of the control process according to the first embodiment and a modification thereof will be described with reference to FIG. 3. FIG. 3 is a flow chart illustrating an example of the procedure of the control process performed by the substrate processing system 1 according to the first embodiment. At the time when the flow chart of FIG. 3 starts, the drain recovery cup 60f is moved up and brought into the first state where the drain recovery cup 60f receives the liquid.

In the control process according to the first embodiment, first, the control unit 18 holds the wafer W carried into the processing unit 16 by the holding unit 31 (step S101). Then, the control unit 18 controls, for example, the substrate processing unit 30 to rotate the wafer W at a predetermined rotation speed (step S102).

Next, the control unit 18 controls the first supply unit 40 to supply the chemical liquid onto the wafer W at a predetermined flow rate (step S103). Then, the control unit 18 stops the supply of the chemical liquid onto the wafer W (step S104).

Next, the control unit 18 controls the second supply unit 50 to perform a rinsing process using the pure water on the wafer W that has been subjected to the liquid processing with the chemical liquid (step S105). Specifically, the control unit 18 controls the second supply unit 50 to supply a rinse liquid onto the wafer W at a predetermined flow rate. Then, the control unit 18 stops the supply of the rinse liquid onto the wafer W.

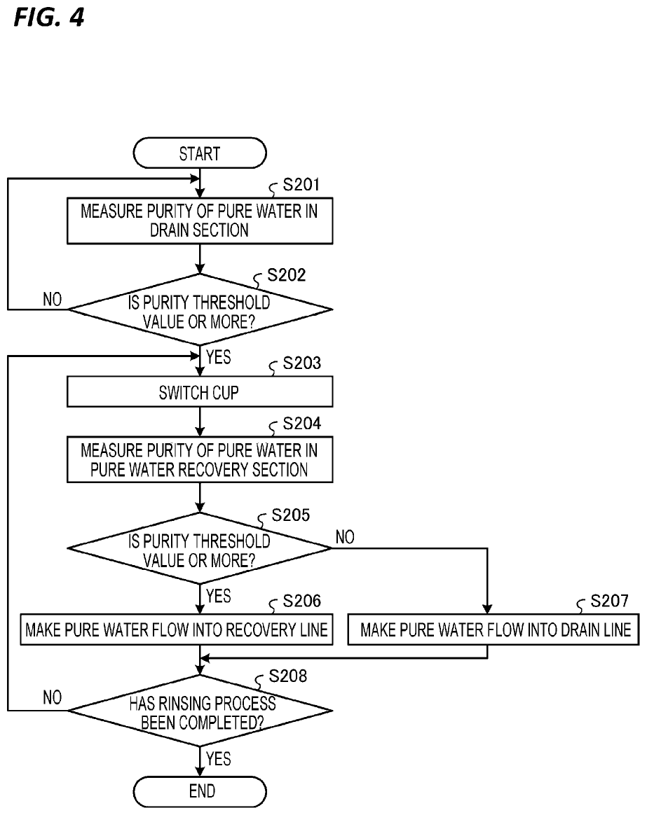

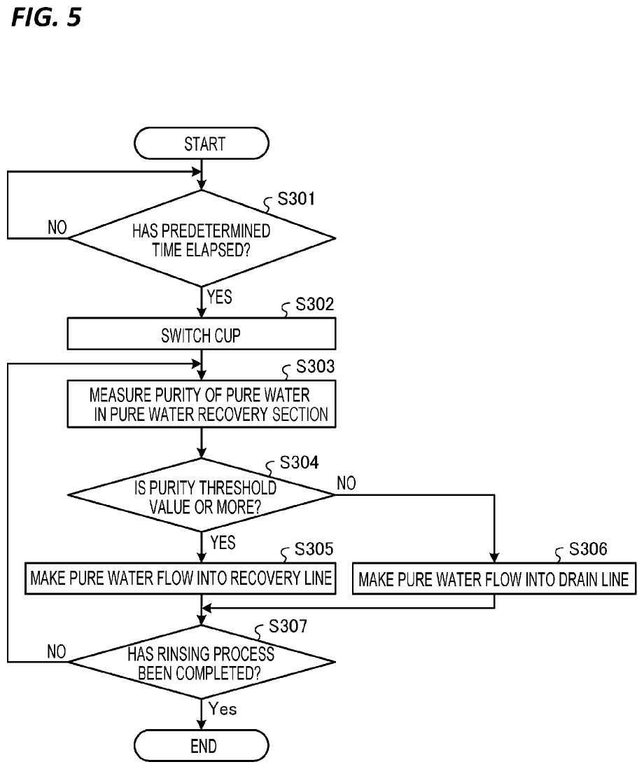

The control unit 18 performs a pure water recovering process during the rinsing process. Specifically, the control unit 18 measures the purity of the pure water by using the measurement unit 62a, and determines whether the pure water is recoverable, based on the measured purity of the pure water. When it is determined that the pure water is recoverable, the control unit 18 controls the switch valve 67 to switch the inflow destination of the pure water from the drain line 65a to the recovery line 65b. The specific procedure of the pure water recovering process performed during the rinsing process will be described later using FIGS. 4 and 5.

Next, the control unit 18 performs a drying process through, for example, a spin dry, on the wafer W that has been subjected to the rinsing process (step S106). Then, the control unit 18 carries the dried wafer W out from the processing unit 16 (step S107), and terminates the series of control processes.

Subsequently, the procedure of the pure water recovering process according to the first embodiment will be described with reference to FIG. 4. FIG. 4 is a flow chart illustrating an example of the procedure of the pure water recovering process performed by the substrate processing system 1 according to the first embodiment. With the start of the rinsing process of step S105 of FIG. 3 described above, the pure water recovering process of the present flow chart starts.

First, the control unit 18 measures the purity of the pure water flowing through the drain section 60e by using the drain measurement unit 62b (step S201). Then, the control unit 18 determines whether the measured purity of the pure water is a predetermined threshold value or more, in other words, whether the pure water is recoverable (step S202). When it is determined that the purity of the pure water is the threshold value or more (step S202, Yes), the control unit 18 controls the lift mechanism 70 to switch from the first state where the drain recovery cup 60f receives the liquid, to the second state where the pure water recovery cup 60a receives the liquid (step S203). Meanwhile, when it is determined that the purity of the pure water is less than the threshold value (step S202, No), the control unit 18 returns the process to step S201.

Next, the control unit 18 measures the purity of the pure water flowing through the pure water recovery section 60d by using the measurement unit 62a (step S204), and determines whether the measured purity of the pure water is a predetermined threshold value or more (step S205). The threshold value in the present process is the same as the threshold value of step S202.

When it is determined that the purity of the pure water is the threshold value or more (step S205, Yes), the control unit 18 controls the switch valve 67 such that the pure water flows into the recovery line 65b (step S206). Meanwhile, when it is determined that the purity of the pure water is less than the threshold value (step S205, No), the control unit 18 controls the switch valve 67 such that the pure water flows into the drain line 65a (step S207). In the present process, even in a case where the chemical liquid is accidentally mixed during the recovery of the pure water in the second state, the low-purity pure water into which the chemical liquid is mixed may be made flow into the drain line 65a. Thus, the low-purity pure water may be suppressed from flowing into the recovery line 65b, and only the high-purity pure water may be recovered.

Next, the control unit 18 determines whether the rinsing process has been completed (step S208). When it is determined that the rinsing process has been completed (step S208, Yes), the control unit 18 terminates the process of the present flow chart. Then, the control unit 18 performs the drying process of step S106 of FIG. 3. Meanwhile, when it is determined that the rinsing process has not been completed (step S208, No), the control unit 18 returns the process to step S204. That is, the control unit 18 continues the process of switching the inflow destination of the pure water according to the purity of the pure water, until the rinsing process is completed.

As described above, the substrate processing system 1 of the first embodiment measures the purity of the pure water using the drain measurement unit 62b during the supply of the pure water onto the wafer W by the second supply unit 50, in the first state where the drain recovery cup 60f receives the liquid. Then, when it is determined based on the measured purity of the pure water that the pure water is recoverable, the substrate processing system of the first embodiment controls the lift mechanism 70 to switch from the first state to the second state where the pure water recovery cup 60a receives the liquid.

When it is determined to recover the pure water, in a case where the chemical liquid adheres to the pure water recovery cup 60a, the chemical liquid adhering to the pure water recovery cup 60a may be mixed into the pure water, resulting in the decrease in purity of the pure water. In contrast, the substrate processing system 1 according to the first embodiment includes the multi-tiered cups, which may suppress the flow of the chemical liquid into the pure water recovery cup 60a, so that the decrease in purity of the pure water may be suppressed. When the decrease in purity of the pure water is suppressed, it is possible to reduce the amount of pure water that is necessarily discarded until reaching a desired recoverable purity, so that the recovery efficiency of the pure water improves.

FIG. 5 is a flow chart illustrating another example of the procedure of the pure water recovering process performed by the substrate processing system 1 according to the first embodiment.

In the pure water recovering process according to another example, first, the control unit 18 determines whether a predetermined time has elapsed since the start of the rinsing process (step S301). Here, the predetermined time refers to a time required until the purity of the pure water reaches a predetermined threshold value or more. For example, the predetermined time is obtained by measuring, multiple times, the time from the start of the rinsing process until the purity of the pure water reaches the threshold value or more, and calculating the average time. For example, the measurement unit 62a as a conductivity meter measures the variation of the conductivity of the pure water during the rinsing process, and measures the time required until the measured conductivity becomes a predetermined value or less (e.g., 15 μS/cm). The measurement is performed multiple times to obtain the average value of the time required until the conductivity becomes the predetermined value or less. The obtained average time is registered in recipe information as the time required until the purity of the pure water reaches the predetermined threshold value or more, i.e., the predetermined time.

When it is determined that the predetermined time has elapsed (step S301, Yes), the control unit 18 controls the lift mechanism 70 to switch from the first state to the second state (step S302). Since the process of subsequent steps S303 to S307 is similar to the process of steps S204 to S208 of FIG. 4, descriptions thereof are omitted.

As described above, the substrate processing system 1 of the first embodiment controls the second supply unit 50 to start the supply of the pure water onto the substrate in the first state where the drain recovery cup 60f receives the liquid, and after the predetermined time elapses since the start of the supply of the pure water, controls the lift mechanism 70 to switch from the first state to the second state. Thereafter, the measurement unit 62a measures the purity of the pure water, and when it is determined based on the measured purity of the pure water that the pure water is recoverable, the switch valve 67 is controlled to switch the inflow destination of the pure water from the drain line 65a to the recovery line 65b. According to this process, the high-purity pure water may be recovered with fewer components, without using the drain measurement unit 62b of the drain section 60e.

### Configuration of Pure Water Recovery System

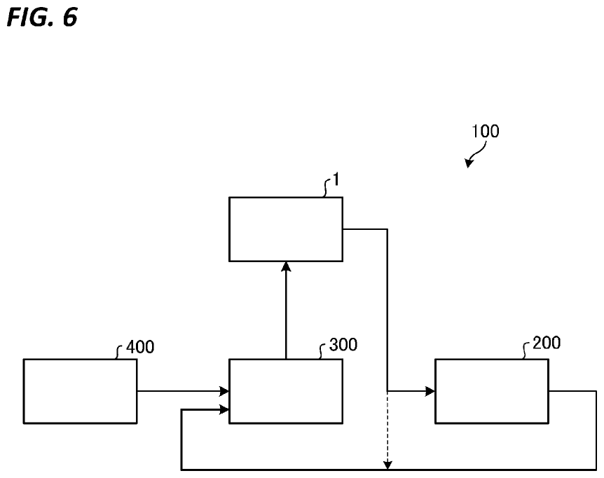

Next, descriptions will be made on an example of a configuration of a supply system 100 according to the first embodiment with reference to FIG. 6. FIG. 6 is a block diagram illustrating an example of the configuration of the supply system 100 according to the first embodiment.

The supply system 100 according to the first embodiment includes the substrate processing system 1 described above, a regeneration system 200, a generation system 300, and a raw water processing system 400. The substrate processing system 1 measures the purity of the pure water during the rinsing process of the substrate, and recovers the pure water determined to be recoverable. Specifically, the control unit 18 of the substrate processing system 1 controls the switch valve 67, such that the pure water determined to be recoverable flows into the recovery line 65b.

The regeneration system 200 is connected to the recovery line 65b of the substrate processing system 1, and performs a regeneration process on the pure water recovered from the recovery line 65b. The regeneration process includes, for example, an activated carbon filtration process, an ion exchange process, and a UV irradiation process.

The generation system 300 is connected to the regeneration system 200, and generates new pure water from the pure water subjected to the regeneration process by the regeneration system 200 and raw water supplied from the raw water processing system 400 to be described later. Then, the generation system 300 supplies the generated new pure water to the second supply unit 50 of the substrate processing system 1. The generation system 300 generates the new pure water by performing, for example, a vacuum deaeration process, an ion exchange process, and a UV irradiation process on the pure water subjected to the regeneration process and the raw water.

The raw water processing system 400 is connected to the generation system 300, and supplies, to the generation system 300, processed raw water obtained by removing a suspended matter or an organic matter from raw water such as city water or industrial water.

According to the supply system 100 of the embodiment, the high-purity pure water recovered by the substrate processing system 1 may be reused, and costs for generating the pure water may be reduced. The regeneration system 200 may not be an essential component of the supply system 100 according to the embodiment, and the generation system 300 may be connected to the recovery line 65b of the substrate processing system 1 without being connected to the regeneration system 200. The supply system 100 may not necessarily be equipped with the raw water processing system 400.

As described above, a substrate processing apparatus according to the embodiment (e.g., the substrate processing system 1) includes a holding unit (e.g., the holding unit 31), a first supply unit (e.g., the first supply unit 40), a second supply unit (e.g., the second supply unit 50), a first processing cup (e.g., the drain recovery cup 60f), a second processing cup (e.g., the pure water recovery cup 60a), a drain section (e.g., the drain section 60e), a recovery section (e.g., the pure water recovery section 60d), and a measurement unit (e.g., the measurement unit 62a). The holding unit holds a substrate. The first supply unit supplies a chemical liquid onto the substrate held by the holding unit. The second supply unit supplies a rinse liquid onto the substrate held by the holding unit. The first processing cup is provided around the holding unit. The second processing cup is disposed inside or outside the first processing cup, and receives the rinse liquid supplied onto the substrate. The drain section is provided at the bottom of the first processing cup. The recovery section is provided at the bottom of the second processing cup, and is connected to a drain line (e.g., the drain line 65a) and a recovery line (e.g., the recovery line 65b) via a line switch (e.g., the switch valve 67). The measurement unit is provided in the recovery section, and measures the purity of the rinse liquid.

When it is determined to recover the pure water, in a case where the chemical liquid adheres to the pure water recovery cup 60a, the chemical liquid adhering to the pure water recovery cup 60a may be mixed into the pure water, resulting in the decrease in purity of the pure water. In contrast, the substrate processing apparatus according to the first embodiment includes the multi-tiered cups, which may suppress the flow of the chemical liquid into the pure water recovery cup 60a, so that the decrease in purity of the pure water may be suppressed. When the decrease in purity of the pure water is suppressed, it is possible to reduce the amount of pure water that is necessarily discarded until reaching a desired recoverable purity, so that the recovery efficiency of the pure water improves.

### Modification of First Embodiment

The first embodiment describes an example where two recovery cups are provided to receive the liquid, and are switched based on, for example, the time elapsed from the start of the supply of the pure water or the purity of the pure water. However, the number of recovery cups is not limited to two. For example, the substrate processing apparatus may include three or more recovery cups. As an example, the substrate processing apparatus may include a recovery cup that receives an acid-based chemical liquid, a recovery cup that receives an alkali-based chemical liquid, and a recovery cup that receives the pure water. In this case, the drain section may be provided at the bottom of the recovery cup that receives the pure water, and the measurement unit may be provided in the drain section.

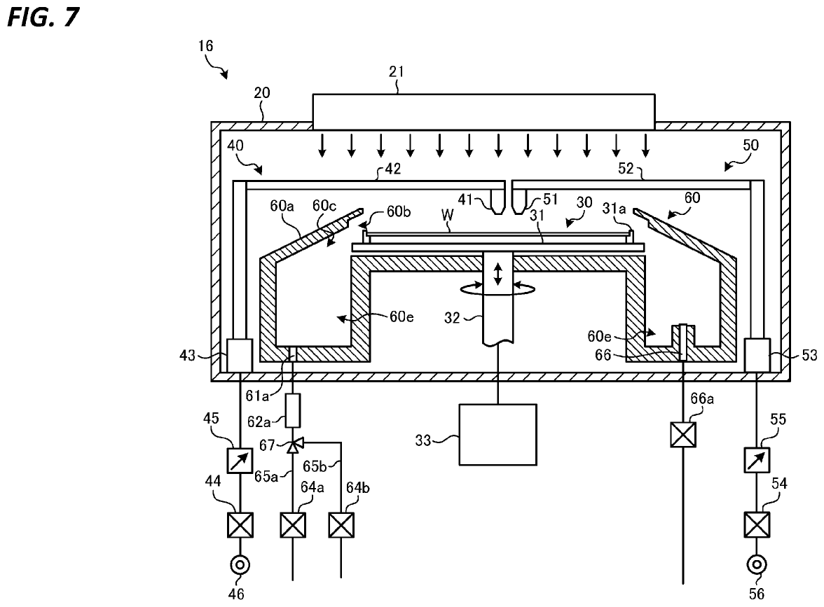

The substrate processing apparatus may include a single recovery cup. FIG. 7 is a schematic view illustrating an example of a specific configuration of a processing unit 16 according to a modification of the first embodiment.

As illustrated in FIG. 7, the processing unit 16 includes one recovery cup 60, and the drain section 60e is provided at the bottom of the recovery cup 60. The drain section 60e is connected to the drain line 65a and the recovery line 65b via the switch valve 67 (an example of a line switch). The drain section 60e is provided with the measurement unit 62a that measures the purity of the pure water.

As for the procedure of the pure water recovery at the case where the substrate processing apparatus includes one recovery cup, first, the control unit 18 measures the purity of the pure water flowing through the drain section 60e using the measurement unit 62a, during the rinsing process. Then, the control unit 18 determines whether the purity of the pure water is a predetermined threshold value or more, and when it is determined that the purity of the pure water is the threshold value or more, the control unit 18 controls the switch valve 67 such that the pure water flows into the recovery line 65b. Meanwhile, when it is determined that the purity of the pure water is less than the threshold value, the control unit 18 controls the switch valve 67 such that the pure water flows into the drain line 65a.

As described above, the substrate treatment system 1 according to the first embodiment measures the purity of the pure water using the measurement unit 62a during the supply of the pure water onto the substrate by the second supply unit 50, and when it is determined based on the measured purity of the pure water that the pure water is recoverable, controls the switch valve 67 to switch the inflow destination of the pure water from the drain line 65a to the recovery line 65b. According to this process, even in a case where the processing liquid adhering to the substrate or the recovery cup is mixed into the pure water, which decreases the purity of the pure water flowing through the drain section, the pure water may be suppressed from flowing into the recovery line, and only the high-purity pure water may be recovered.

As described above, the substrate processing apparatus according to the first embodiment (e.g., the substrate processing system 1) includes a holding unit (e.g., the holding unit 31), a processing cup (e.g., the recovery cup 60), a first supply unit (e.g., the first supply unit 40), a second supply unit (e.g., the second supply unit 50), a drain section (e.g., the drain section 60e), and a measurement unit (e.g., the measurement unit 62a). The holding unit holds a substrate. The processing cup is provided around the holding unit. The first supply unit supplies a chemical liquid onto the substrate held by the holding unit. The second supply unit supplies a rinse liquid onto the substrate held by the holding unit. The drain section is provided at the bottom of the processing cup, and is connected to a drain line (e.g., the drain line 65a) and a recovery line (e.g., the recovery line 65b) via a line switch (e.g., the switch valve 67). The measurement unit is provided in the drain section, and measures the purity of the rinse liquid.

In the substrate processing apparatus according to the first embodiment, the measurement unit for measuring the purity of the pure water is provided in the drain section. According to this configuration, the switch of the inflow destination becomes possible according to when the purity is high or low, and therefore, the low-purity pure water is suppressed from flowing into the recovery line, so that only the high-purity pure water may be made flow into the recovery line. Thus, the high-purity pure water may be recovered. According to the configuration, as compared to the case where the plurality of processing cups are provided, the pure water recovering process may be more simply performed with fewer components.

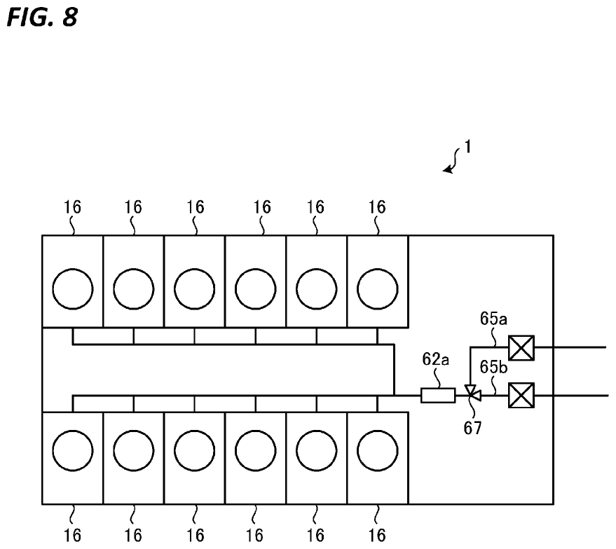

The first embodiment describes an example where the measurement unit 62a, the switch valve 67, the drain line 65a, and the recovery line 65b are provided for each processing unit 16. Without being limited thereto, at least one measurement unit 62a, switch valve 67, drain line 65a, and recovery line 65b may be provided in the entire substrate processing system. For example, as illustrated in FIG. 8, the measurement unit 62a and the switch valve 67 (an example of a line switch) may be provided in a collective drain pipe (an example of a drain section) through which the drain liquid of the plurality of processing units 16 flows, and based on a measurement result from the measurement unit 62a, it may be determined whether to recover the pure water. When the pure water is recoverable, the switch valve 67 may be controlled such that the pure water flows into the recovery line 65b, and when the pure water is not recoverable, the switch valve 67 may be controlled such that the pure water flows into the drain line 65a. According to this configuration, a small number of measurement units is used, so that the pure water recovering process may be more easily performed with fewer components.

FIG. 8 represents an example where the measurement unit 62a, the switch valve 67, the drain line 65a, and the recovery line 65b are disposed inside the substrate processing system 1. Without being limited thereto, the switch valve 67, the drain line and the recovery line 65b may be disposed outside the substrate processing system 1.

The first embodiment describes an example where the pure water recovery cup 60a is provided outside the drain recovery cup 60f. However, the pure water recovery cup 60a may be provided inside the drain recovery cup 60f.

### Second Embodiment

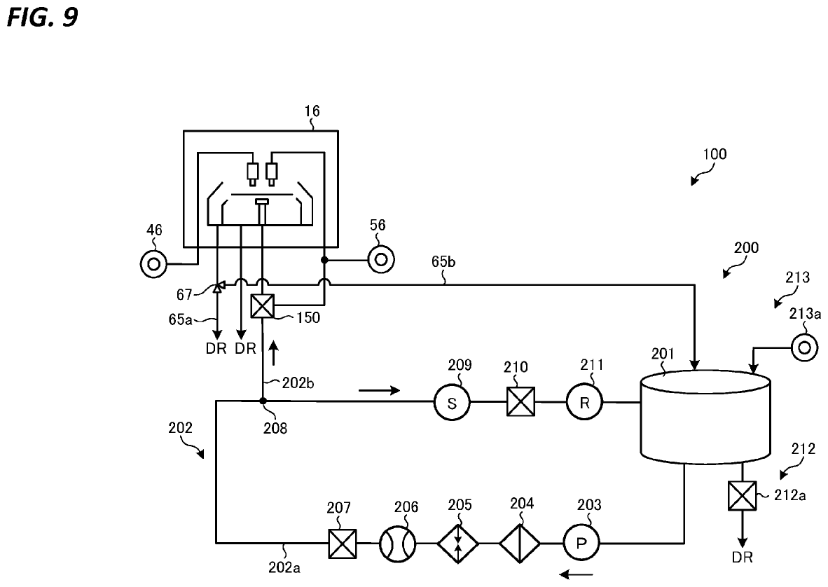

Next, descriptions will be made on an example of a configuration of a supply system 100 according to a second embodiment, with reference to FIG. 9. FIG. 9 is a schematic block diagram illustrating an example of the configuration of the supply system 100 according to the second embodiment.

As illustrated in FIG. 9, the supply system 100 includes the processing unit 16, the regeneration system 200, and a supply line 202b that connects the processing unit 16 and the regeneration system 200. Without being limited to the example of FIG. 9, the processing unit 16 may be the substrate processing system 1 (an example of a substrate processing apparatus).

The regeneration system 200 is connected to the recovery line 65b of the processing unit 16, and performs the regeneration process on the pure water recovered from the recovery line 65b. The regeneration system 200 includes a storage unit 201 and a circulation unit 202. The storage unit 201 stores the pure water recovered from the recovery line 65b. The storage unit 201 includes a discharge unit 212 that discharges the pure water stored in the storage unit 201. The pure water stored in the storage unit 201 is discharged to the outside of the regeneration system 200 through a valve 212a. The storage unit 201 may include a DIW supply unit 213 that supplies DIW from a DIW supply source 213a storing DIW.

The circulation unit 202 returns regenerated pure water that has been sent from the storage unit 201, to the storage unit 201. The circulation unit 202 includes a circulation line 202a. The circulation line 202a is a circulation line that starts from the storage unit 201 and returns to the storage unit 201. One end of the circulation line 202a is connected to an outlet formed, for example, at the bottom of the storage unit 201, and the other end thereof is connected to an inlet formed, for example, at the upper portion of the side surface of the storage unit 201. The circulation line 202a forms a circulation path flowing from the outlet to the inlet.

The circulation line 202a is provided with a pump 203, a filter 204, a temperature regulation unit 205, a flow rate meter 206, a valve 207, a branch 208, a measurement unit 209 (an example of a third measurement unit), a valve 210, and a back pressure valve 211 in this order from upstream with the storage unit 201 being a reference point (the most upstream position).

The pump 203 sends the regenerated pure water in the storage unit 201, to the circulation line 202a. The filter 204 removes solid impurities (particles) from the regenerated pure water flowing in the circulation line 202a. The temperature regulation unit 205 regulates the regenerated pure water flowing in the circulation line 202a to a temperature suitable for the rinsing process. The temperature regulation unit 205 regulates the regenerated pure water flowing in the circulation line 202a to, for example, 25° C. The temperature of the regenerated pure water flowing in the circulation line 202a may rise due to the influence of, for example, the pump 203, but the temperature regulation unit 205 may prevent the temperature rise.

The flow meter 206 regulates the flow rate of the regenerated pure water flowing in the circulation line 202a. The plurality of valves 207 and 210 open and close the circulation line 202a. From the branch 208, the supply line 202b branches off to supply the regenerated pure water subjected to the regeneration process by the regeneration system 200 to the processing unit 16. That is, the supply line 202b is a branch line that branches off from the circulation path 202a.

The measurement unit 209 measures the purity of the regenerated pure water flowing in the circulation line 202a. The measurement unit 209 is, for example, a conductivity meter, a concentration meter, or a specific resistance meter. As a result, the purity of the regenerated pure water flowing in the circulation line 202a may be checked, and the liquid supply to the processing unit 16 or the liquid drainage from the storage unit 201 may be controlled. The back pressure valve 211 regulates the pressure of the regenerated pure water flowing in the circulation line 202a, to a desired pressure.

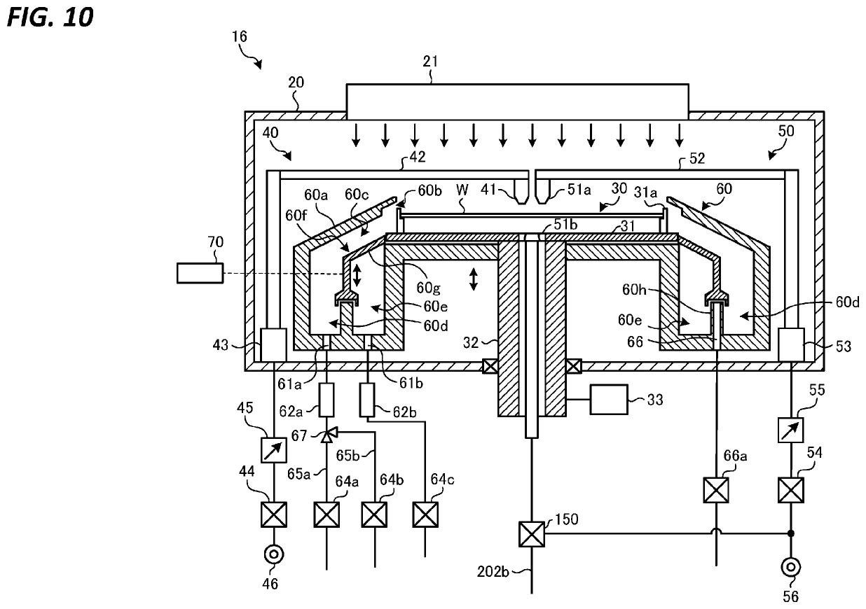

Next, the configuration of the processing unit 16 according to the second embodiment will be described with reference to FIG. 10. FIG. 10 is a schematic view illustrating an example of the specific configuration of the processing unit 16. The first embodiment describes an example where the rinsing process is performed on the front surface (upper surface) of the wafer W. However, the rinsing process may also be performed on the back surface (lower surface) of the wafer W in the same manner as performed on the front surface of the wafer W. The second embodiment describes an example where the rinsing process is performed on the back surface of the wafer W using the regenerated pure water subjected to the regeneration process by the regeneration system 200. In the following descriptions hereinafter, the front surface (upper surface) of the wafer W will be referred to as the device surface, and the back surface (lower surface) of the wafer W will be referred to as the non-device surface.

The second supply unit 50 includes a first nozzle 51a and a second nozzle 51b. Similarly to the nozzle 51 in the first embodiment, the first nozzle 51a supplies the pure water onto the front surface of the wafer W held by the holding unit 31.

The second nozzle 51b supplies the pure water to the back surface of the wafer W held by the holding unit 31. The second nozzle 51b is disposed inside a through hole formed in the support column 32. The second nozzle 51b is connected to the DIW supply source 56 or the supply line 202b via a switch valve 150. The switch valve 150 switches the pure water to flow into the second nozzle 51b, between the pure water supplied from the DIW supply source 56 and the pure water supplied from the supply line 202b. In other words, the switch valve 150 switches the connection destination of the second nozzle 51b between the DIW supply source 56 and the supply line 202b.

In the description hereinafter, the pure water supplied from the DIW supply source 56 will be referred to as a “fresh liquid of pure water,” and the pure water supplied from the supply line 202b will be referred to as “regenerated pure water.” When the fresh liquid of pure water and the regenerated pure water do not need to be distinguished, they may be referred to simply as “pure water.”

As described above, the regenerated pure water that has been subjected to the regeneration process is reused for the rinsing process of the wafer W, so that the use amount of pure water may be reduced. Further, by supplying the regenerated pure water only to the non-device surface of the wafer W, the cleanliness of the device surface of the wafer W may be maintained.

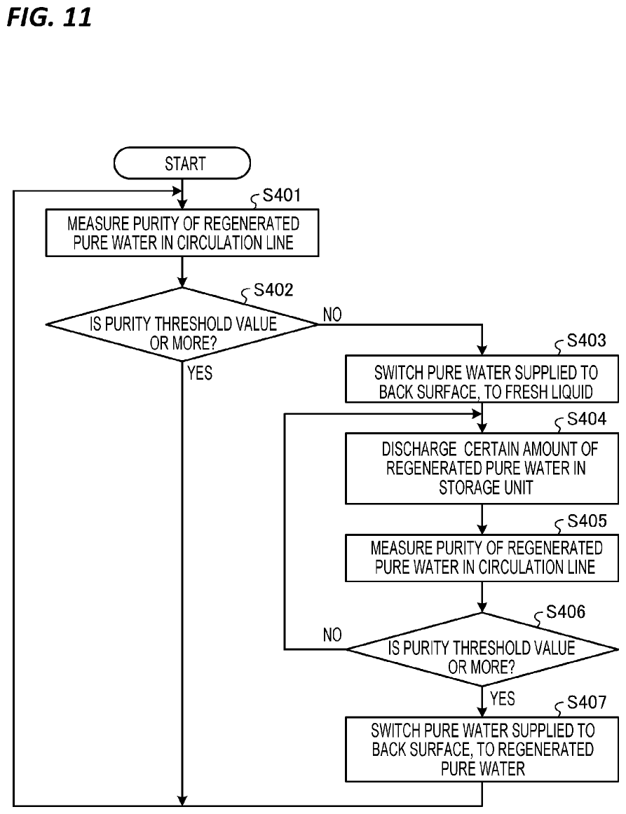

Next, the procedure of the control process according to the second embodiment will be described with reference to FIG. 11. FIG. 11 is a flow chart illustrating an example of the procedure of the control process performed by the supply system 100 according to the second embodiment.

First, the control unit 18 measures the purity of the regenerated pure water flowing in the circulation line 202a by using the measurement unit 209 (step S401). Then, the control unit 18 determines whether the measured purity of the regenerated pure water is a predetermined threshold value or more, in other words, whether the regenerated pure water is usable for the rinsing process on the back surface of the wafer W (step S402). The threshold value in the present process is, for example, the same as the threshold value in steps S202 and S205 of FIG. 4.

When it is determined that the purity of the regenerated pure water is less than the threshold value (step S402, No), the control unit 18 controls the switch valve 150 to switch the pure water supplied to the back surface of the wafer W, to the fresh liquid of pure water (step S403). That is, the control unit 18 closes the supply line 202b that supplies the regenerated pure water from the regeneration system 200 to the processing unit 16.

Next, the control unit 18 controls the discharge unit 212 to discharge a certain amount of regenerated pure water stored in the storage unit 201 (step S404).

Next, the control unit 18 re-measures the purity of the regenerated pure water flowing in the circulation line 202a by using the measurement unit 209 (step S405). Then, the control unit 18 determines whether the measured purity of the regenerated pure water is a predetermined threshold value or more (step S406). The threshold value in the present process is the same as the threshold value of step S402.

When it is determined that the purity of the regenerated pure water is the threshold value or more (step S406, Yes), the control unit 18 controls the switch valve 150 to switch the pure water supplied to the back surface of the wafer W to the regenerated pure water (step S407). That is, the control unit 18 opens the supply line 202b that supplies the regenerated pure water from the regeneration system 200 to the processing unit 16.

Meanwhile, when it is determined that the purity of the generated pure water is less than the threshold value (step S406, No), the control unit 18 returns the process to step S404. That is, the control unit 18 repeats the process of discharging the regenerated pure water from the storage unit 201 until the purity of the regenerated pure water becomes the threshold value or more.

As described above, the supply system 100 according to the second embodiment measures the purity of the regenerated pure water flowing in the circulation line 202a by using the measurement unit 209. When the measured purity of the regenerated pure water is the threshold value or more, the supply system 100 controls the second supply unit 50 to eject the regenerated pure water from the second nozzle 51b. When the measured purity of the regenerated pure water is less than the threshold value, the supply system 100 controls the discharge unit 212 to discharge the regenerated pure water stored in the storage unit 201, and controls the second supply unit 50 to eject the fresh liquid of pure water from the second nozzle 51b.

According to the process above, when the purity of the regenerated pure water flowing in the circulation line 202a is the purity usable for the substrate processing, the regenerated pure water may be reused by being used for the substrate processing. When the purity of the regenerated pure water flowing in the circulation line 202a is not the purity usable for the substrate processing, the regenerated pure water of the storage unit 201 may be discharged in a certain amount and circulated, thereby increasing the purity of the regenerated pure water. When the rinsing process is performed using the fresh liquid of pure water in the processing unit 16, the fresh liquid of pure water supplied to the wafer W is recovered in the storage unit 201 through the recovery line 65b. As a result, the purity of the regenerated pure water flowing in the circulation line 202a may be further increased.

Here, descriptions have been made on a case where the threshold value in step S402 is the same as the threshold value for determining whether the pure water is recoverable in the processing unit 16 (steps S202 and S205 of FIG. 4). However, the threshold values may be different from each other. For example, the threshold value in step S402 may be larger than the threshold values of steps S202 and S205. The pure water recovered from the processing unit 16 circulates through the circulation line 202a, so that the impurities thereof are removed, and the purity thereof increases. Thus, even when the purity of the pure water recovered from the processing unit 16 is lower than the purity usable for the substrate processing, the pure water may reach the purity usable for the substrate processing by circulating through the circulation line 202a, and may be reused for the substrate processing. Therefore, the efficiency of the recovery of the pure water from the processing unit 16 may be further improved.

When it is determined that the purity of the regenerated pure water is less than the threshold value (step S402, No), the control unit 18 may control the DIW supply unit 213 to supply the fresh liquid of pure water to the storage unit 201.

Here, descriptions have been made on the example where the back surface of the wafer W is the non-device surface. Without being limited thereto, the non-device surface may be the front surface of the wafer W. In this case, the regenerated pure water may be supplied to the front surface of the wafer W during the rinsing process.

### Third Embodiment

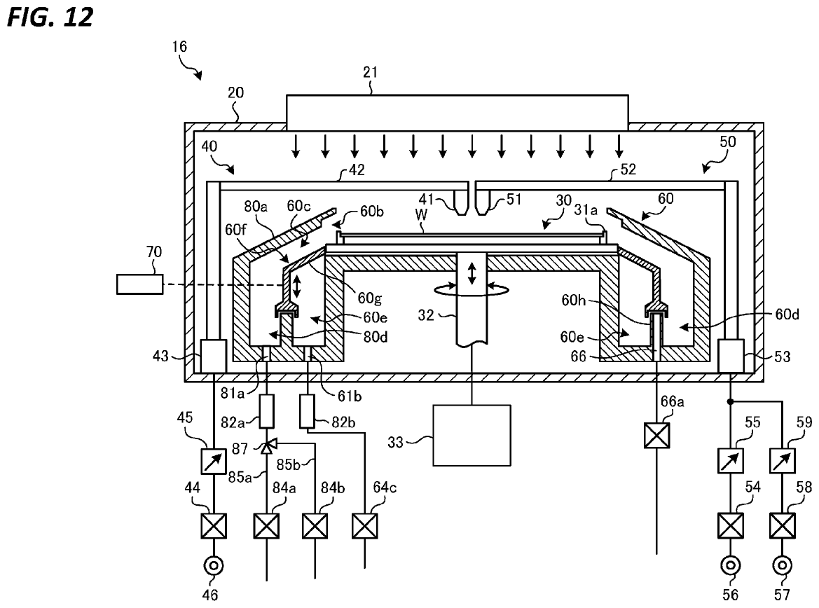

Next, a configuration of a processing unit 16 according to a third embodiment will be described with reference to FIG. 12. FIG. 12 is a schematic view illustrating an example of the specific configuration of the processing unit 16. The first embodiment describes an example where the spin drying is performed as the drying process. However, without being limited thereto, the wafer W may be dried by ejecting a drying liquid such as isopropyl alcohol (IPA) onto the front surface of the wafer W. In this case, the IPA may be recovered during the drying process. In the third embodiment, descriptions will be made on an example where the IPA is used for the drying process of the wafer W, and is recovered during the drying process.

The second supply unit 50 supplies the IPA to the wafer W held by the holding unit 31, to perform the drying process on the wafer W. The IPA is an example of the drying liquid used for the drying process on the wafer W. The second supply unit 50 includes the nozzle 51, the arm 52 that supports the nozzle 51 horizontally, and the swivel/lift mechanism 53 that swivels and moves up/down the arm 52.

The nozzle 51 is connected to an IPA supply source 57 via a valve 58 and a flow rate regulator 59. The IPA supply source 57 is a tank that stores IPA.

The recovery cup 60 (an example of a processing cup) is disposed around the holding unit 31, and collects the liquid scattered from the wafer W due to the rotation of the holding unit 31. The recovery cup 60 may be configured with multi-tiered cups arranged concentrically with the rotation center of the wafer W rotating while being held by the substrate processing unit 30. Specifically, the recovery cup 60 includes an IPA recovery cup 80a (an example of a second processing cup) and the drain recovery cup 60f (an example of a first processing cup).

The IPA recovery cup 80a has a shape that surrounds the portion below the wafer W and the outside of the outer periphery of the wafer W and opens the portion above the wafer W. The IPA recovery cup 80a is provided outside the drain recovery cup 60f. The IPA recovery cup 80a forms the recovery port 60b outside the outer periphery of the wafer W, and forms the recovery space 60c below the wafer W to communicate with the recovery port 60b.

The IPA recovery cup 80a forms the concentric ring-shaped partition wall 60h at the bottom of the recovery space 60c to divide the bottom of the recovery space 60c into an IPA recovery section 80d and the drain section 60e that have a concentric double-ring shape. The IPA recovery section 80d is disposed outside the drain section 60e. In the bottom of the recovery space 60c, the bottom portion where the IPA recovery section 80d is provided is an example of the “bottom of a second processing cup.” In the bottom of the recovery space 60c, the bottom portion where the drain section 60e is provided is an example of the “bottom of a first processing cup.”

A drain port 81a is formed in the IPA recovery section 80d. The discharge path from the drain port 81a is connected to a drain line 85a and a recovery line 85b via a switch valve 87 (an example of a line switch). For example, when the control device 4 controls the switch valve 87 to set the drain line 85a as the inflow destination of a drain liquid, the drain liquid discharged from the drain port 81a flows into the drain line 85a through the valve 84a. Similarly, for example, when the control device 4 controls the switch valve 87 to set the recovery line 85b as the inflow destination of a drain liquid, the drain liquid discharged from the drain port 81a flows into the recovery line 85b through the valve 84b.

The IPA recovery section 80d is provided with a measurement unit 82a (an example of a first measurement unit) that measures the purity of the IPA. The “purity of the IPA” herein refers to the proportion of the IPA, which is a main component, in the IPA. The “high purity of the IPA” indicates that the proportion of the IPA as the main component is high, in other words, that the proportion of components other than the main component is low. The purity of the IPA may be estimated from, for example, the water content of the IPA. Thus, for example, a moisture meter may be used as the measurement unit 62a.

The drain section 60e also is provided with a drain measurement unit 82b (an example of a second measurement unit) that measures the purity of the IPA. The drain measurement unit 82b is, for example, a moisture meter.

For example, when the wafer W is processed by ejecting the chemical liquid onto the wafer W (step S104 of FIG. 3), the control device 4 controls the drive unit 33 of the substrate processing unit 30 to rotate the holding unit 31 at a predetermined rotation speed, and opens the valve 44. As a result, the chemical liquid supplied from the chemical liquid supply source 46 is ejected from the nozzle 41 onto the upper surface of the wafer W. Further, when the wafer W is processed by ejecting the pure water onto the wafer W (step S105 of FIG. 3), the control device 4 controls the drive unit 33 of the substrate processing unit 30 to rotate the holding unit 31 at a predetermined rotation speed, and opens the valve 54. As a result, the DIW supplied from the DIW supply source 56 is ejected from the nozzle 51 onto the upper surface of the wafer W.

At this time, the control device 4 controls the lift mechanism 70 to move up the drain recovery cup 60f, thereby forming the flow path extending from the recovery port 60b to the drain port 61b of the drain section 60e.

As a result, the chemical liquid or pure water supplied onto the wafer W is expelled toward the outside of the outer periphery of the wafer W due to the centrifugal force caused by the rotation of the wafer W, and is recovered from the recovery port 60b into the drain section 60e. Then, the chemical liquid or pure water is discharged from the drain port 61b. In other words, the state where the drain recovery cup 60f moves up indicates the state where the drain recovery cup 60f receives the liquid (hereinafter, also referred to as a third state).

For example, when the wafer W is processed by ejecting the IPA to the wafer W (step S106 of FIG. 3), the control device 4 controls the drive unit 33 to rotate the holding unit 31 at a predetermined rotation speed, and opens the valve 58. As a result, the IPA supplied from the IPA supply source 57 is ejected from the nozzle 51 to the upper surface of the wafer W.

At this time, the control device 4 controls the lift mechanism 70 to move down the drain recovery cup 60f, thereby forming the flow path extending from the recovery port 60b to the drain port 81a of the IPA recovery section 80d.

As a result, the IPA supplied to the wafer W is expelled toward the outside of the outer periphery of the wafer W due to the centrifugal force caused by the rotation of the wafer W, and is recovered from the recovery port 60b of the IPA recovery cup 80a into the IPA recovery section 80d of the recovery space 60c. Then, the IPA is discharged from the drain port 81a. In other words, the state where the drain recovery cup 60f moves down indicates the state where the IPA recovery cup 80a receives the liquid (hereinafter, also referred to as a fourth state).

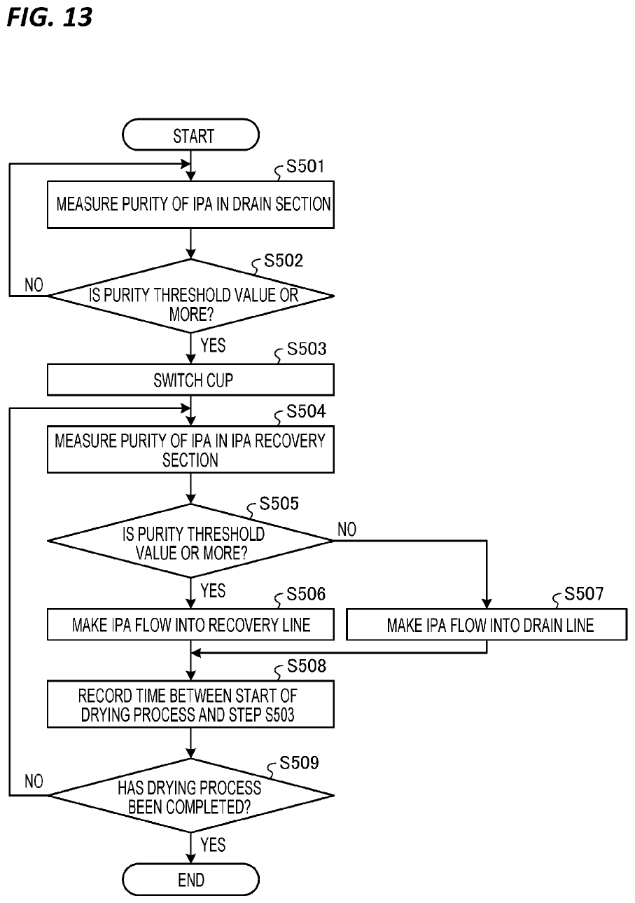

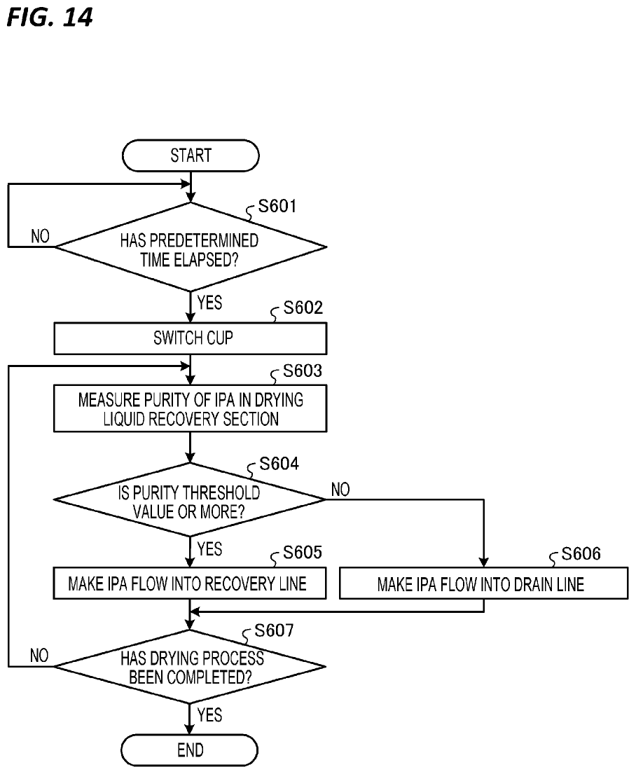

Subsequently, the procedure of the IPA recovering process according to the third embodiment will be described with reference to FIGS. 13 and 14. FIG. 13 is a flow chart illustrating an example of the procedure of the IPA recovering process performed by the substrate processing system 1 according to the third embodiment. With the start of the drying process in step S106 of FIG. 3 described above, the IPA recovering process of the present flow chart starts.

At the time when the flow chart of FIG. 13 starts, the drain recovery cup 60f is moved up to be brought into the third state where the drain recovery cup 60f receives the liquid. That is, while the first embodiment describes an example where the cup switching process is performed during the rinsing process, the third embodiment assumes that the cup switching process is not performed during the rinsing process, and the drain recovery cup 60F receives the pure water in the same manner as that for the chemical liquid.

First, the control unit 18 measures the purity of the IPA flowing through the drain section 60e by using the drain measurement unit 82b (step S501). Then, the control unit 18 determines whether the measured purity of the IPA is a predetermined threshold value or more, in other words, whether the IPA is recoverable (step S502). When it is determined that the purity of the IPA is the threshold value or more (step S502, Yes), the control unit 18 controls the lift mechanism 70 to switch from the third state where the drain recovery cup 60f receives the liquid, to the fourth state where the IPA recovery cup 80a receives the liquid (step S503). Meanwhile, when it is determined that the purity of the IPA is less than the threshold value (step S502, No), the control unit 18 returns the process to step S501.

Next, the control unit 18 measures the purity of the IPA flowing through the IPA recovery section 80d by using the measurement unit 82a (step S504), and determines whether the measured purity of the IPA is a predetermined threshold value or more (step S505). The threshold value in the present process is the same as the threshold value in step S502.

When it is determined that the purity of the IPA is the threshold value or more (step S505, Yes), the control unit 18 controls the switch valve 87 such that the IPA flows into the recovery line 85b (step S506). Meanwhile, when it is determined that the purity of the IPA is less than the threshold value (step S505, No), the control unit 18 controls the switch valve 87 such that the IPA flows into the drain line 85a (step S507). In the present process, even in a case where the chemical liquid is accidentally mixed during the recovery of the IPA in the second state, the low-purity IPA into which the chemical liquid is mixed may be made flow into the drain line 85a. Thus, the low-purity IPA may be suppressed from flowing into the recovery line 85b, and only the high-purity IPA may be recovered.

Next, the control unit 18 records the time between the start of the drying process and step S503. Specifically, the control unit 18 records the time from the start of the IPA supply to the wafer W until the purity of the IPA flowing through the drain section 60e becomes the threshold value or more. This time is a time required until the purity of the IPA reaches the predetermined threshold value or more, and may be used to determine whether to switch from the drain recovery cup 60f to the IPA recovery cup 80a. This configuration will be described later with reference to FIG. 14.

Next, the control unit 18 determines whether the drying process has been completed (step S509). When it is determined that the drying process has been completed (step S509, Yes), the control unit 18 terminates the process of the present flow chart. Then, the control unit 18 performs the carry-out process of step S107 in FIG. 3. Meanwhile, when it is determined that the drying process has not been completed (step S509, No), the control unit 18 returns the process to step S504. That is, the control unit 18 continues the process of switching the inflow destination of the IPA according to the purity of the IPA until the drying process is completed.

As described above, the substrate processing system 1 according to the third embodiment measures the purity of the IPA by using the drain measurement unit 82b, while the IPA is being supplied to the wafer W by the second supply unit 50, in the first state where the drain recovery cup 60f receives the liquid. Then, when it is determined based on the measured purity of the IPA that the IPA is recoverable, the substrate processing system 1 of the third embodiment controls the lift mechanism 70 to switch from the third state to the fourth state where the IPA recovery cup 80a receives the liquid.

When it is determined to recover the IPA, in a case where the chemical liquid or pure water adheres to the IPA recovery cup 80a, the chemical liquid or pure water adhering to the IPA recovery cup 80a may be mixed into the IPA, resulting in the decrease in purity of the IPA. In contrast, the substrate processing system 1 according to the third embodiment includes the multi-tiered cups, which may suppress the flow of the chemical liquid or pure water into the IPA recovery cup 80a, so that the decrease in purity of the IPA may be suppressed. When the decrease in purity of the IPA is suppressed, it is possible to reduce the amount of IPA that is necessarily discarded until reaching a desired recoverable purity, so that the recovery efficiency of the IPA improves.

FIG. 14 is a flow chart illustrating another example of the procedure of the IPA recovering process performed by the substrate processing system 1 according to the third embodiment.

In the IPA recovering process according to another example, first, the control unit 18 determines whether a predetermined time has elapsed since the start of the drying process (step S601). Here, the predetermined time refers to a time required until the purity of the IPA becomes the predetermined threshold value or more. For example, as described above with reference to FIG. 13, the predetermined time is obtained by measuring, multiple times, the time from the start of the drying process until the purity of the IPA reaches the threshold value or more, and calculating the average time. As an example, the measurement unit 82a as a moisture meter measures the variation of the water content of the IPA during the drying process, and measures the time required until the measured water content becomes a predetermined value or less (e.g., 15%). The measurement is performed multiple times to obtain the average value of the time required until the water content becomes the predetermined value or less. The obtained average time is registered in recipe information as the time required until the purity of the IPA reaches the predetermined threshold value or more, i.e., the predetermined time.

When it is determined that the predetermined time has elapsed (step S601, Yes), the control unit 18 controls the lift mechanism 70 to switch from the first state to the second state (step S602). Since the process of subsequent steps S603 to S607 is identical to the process of steps S504 to S508 of FIG. 13, descriptions thereof are omitted.

As described above, the substrate processing system 1 according to the third embodiment controls the second supply unit 50 to start the supply of the IPA to the substrate in the first state where the drain recovery cup 60f receives the liquid, and after the predetermined time elapses since the start of the supply of the IPA, controls the lift mechanism 70 to switch from the first state to the second state. Thereafter, the purity of the IPA is measured using the measurement unit 82a, and when it is determined based on the measured purity of the IPA that the IPA is recoverable, the switch valve 87 is controlled to switch the inflow destination of the IPA from the drain line 85a to the recovery line 85b. According to this process, the high-purity IPA may be recovered with a small number of components, without using the drain measurement unit 82b in the drain section 60e.

For example, while the foregoing embodiment describes an example where the rinse liquid used for the rinsing process on the wafer W is the pure water, the rinse liquid is not limited thereto. Instead of the pure water, for example, functional water such as ammonia water, ozone water, or CO₂ water may be used as the rinse liquid. Further, while the foregoing embodiment describes an example where the drying liquid used for the drying process of the wafer W is the IPA, the drying liquid is not limited thereto. Instead of the IPA, for example, organic solvents such as acetone and methanol may be used as the drying liquid.

According to the present disclosure, a high-purity rinse or drying liquid may be recovered.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a holder configured to hold a substrate;
a processing cup provided around the holder;
a first supply configured to supply a chemical liquid to the substrate held by the holder;
a second supply configured to supply a rinse liquid or a drying liquid to the substrate held by the holder;
a drain block provided at a bottom of the processing cup, and connected to a drain line and a recovery line via a line switch; and
a first gauge provided in the drain block, and configured to measure a purity of the rinse liquid or the drying liquid.

2. A substrate processing apparatus comprising:
a holder configured to hold a substrate;
a first supply configured to supply a chemical liquid to the substrate held by the holder;
a second supply configured to supply a rinse liquid or a drying liquid to the substrate held by the holder;
a first processing cup provided around the holder;
a second processing cup disposed inside or outside the first processing cup, and configured to receive the rinse liquid or the drying liquid supplied to the substrate;
a drain block provided at a bottom of the first processing cup;
a recovery block provided at a bottom of the second processing cup, and connected to a drain line and a recovery line via a line switch;
a first gauge provided in the recovery block, and configured to measure a purity of the rinse liquid or the drying liquid.

3. The substrate processing apparatus according to claim 2, further comprising:
a second gauge provided in the drain block, and configured to measure the purity of the rinse liquid or the drying liquid.

4. The substrate processing apparatus according to claim 1, further comprising:
a controller configured to measure the purity of the rinse liquid or the drying liquid by using the first gauge while the rinse liquid or the drying liquid is being supplied to the substrate by the second supply, determine whether the rinse liquid or the drying liquid is recoverable based on the purity of the rinse liquid or the drying liquid measured by the gauge, and when determined that the rinse liquid or the drying liquid is recoverable, control the line switch to switch an inflow destination of the rinse liquid or the drying liquid from the drain line to the recovery line.

5. The substrate processing apparatus according to claim 2, further comprising:
a cup switch configured to switch between a first state where the first processing cup receives a liquid and a second state where the second processing cup receives a liquid; and
a controller configured to control the second supply, the cup switch, and the line switch,
wherein the controller controls the second supply to start a supply of the rinse liquid or the drying liquid to the substrate in the first state, and after a predetermined time elapses from the start of the supply of the rinse liquid or the drying liquid, controls the cup switch to switch from the first state to the second state, and
wherein the controller measures the purity of the rinse liquid or the drying liquid by using the first gauge, determines whether the rinse liquid or the drying liquid is recoverable based on the purity of the rinse liquid or the drying liquid measured by the first gauge, and when determined that the rinse liquid or the drying liquid is recoverable, controls the line switch to switch an inflow destination of the rinse liquid or the drying liquid from the drain line to the recovery line.

6. The substrate processing apparatus according to claim 3, further comprising:
a cup switch configured to switch between a first state where the first processing cup receives a liquid and a second state where the second processing cup receives a liquid; and
a controller configured to control the cup switch,
wherein in the first state, the controller measures the purity of the rinse liquid or the drying liquid by using the second gauge while the rinse liquid or the drying liquid is being supplied to the substrate by the second supply, determines whether the rinse liquid or the drying liquid is recoverable based on the purity of the rinse liquid or the drying liquid measured by the second gauge, and when determined that the rinse liquid or the drying liquid is recoverable, controls the cup switch to switch from the first state to the second state.

7. A supply system comprising:
a regeneration system connected to the recovery line of the substrate processing apparatus according to claim 1, and configured to perform a regeneration process on the rinse liquid recovered from the recovery line;
a generation system connected to the regeneration system, and configured to generate a new rinse liquid from a regenerated rinse liquid obtained by the regeneration process and processed raw water, and supply the new rinse liquid generated by the generation system to the second supply of the substrate processing apparatus; and
a raw water processing system connected to the generation system, and configured to supply the processed raw water to the generation system.

8. A supply system comprising:
a regeneration system connected to the recovery line of the substrate processing apparatus according to claim 1, and configured to perform a regeneration process on the rinse liquid recovered from the recovery line; and
a supply line connected to the regeneration system, and configured to supply a regenerated rinse liquid obtained by the regeneration process to the second supply of the substrate processing apparatus,
wherein the second supply includes
a first nozzle configured to supply the rinse liquid to a front surface of the substrate held by the holder, and
a second nozzle configured to supply the rinse liquid to a back surface of the substrate held by the holder, and connected to the supply line.

9. The supply system according to claim 8, wherein the regeneration system includes
a storage configured to store the rinse liquid recovered from the recovery line,
a circulation line configured to return the regenerated rinse liquid sent from the storage, to the storage, and
a third gauge provided in the circulation line, and configured to measure a purity of the regenerated rinse liquid,
wherein the supply line branches from the circulation line.

10. The supply system according to claim 9, further comprising:
a discharge block configured to discharge the regenerated rinse liquid from the storage; and
a controller configured to control the second supply and the discharge block,
wherein the second supply further includes
a switch valve configured to switch a connection destination of the second nozzle between a supply source of a fresh liquid of the rinse liquid and the supply line,
wherein the controller controls the third gauge to measure the purity of the regenerated rinse liquid flowing in the circulation line,
when the purity of the regenerated rinse liquid measured by the third gauge is equal to or more than a threshold value, the controller controls the second supply to eject the regenerated rinse liquid from the second nozzle, and
when the purity of the regenerated rinse liquid measured by the third gauge is less than the threshold value, the controller controls the discharge block to discharge the regenerated rinse liquid stored in the storage, and controls the second supply to eject the fresh liquid of the rinse liquid from the second nozzle.

11. A substrate processing method comprising:
providing the substrate processing apparatus according to claim 1;
supplying the rinse liquid or the drying liquid to the substrate from the second supply;
measuring the purity of the rinse liquid or the drying liquid by using the first gauge in the supplying;
determining whether the rinse liquid or the drying liquid is recoverable based on the purity of the rinse liquid or the drying liquid measured in the measuring; and
when determined that the rinse liquid or the drying liquid is recoverable, controlling the line switch to switch an inflow destination of the rinse liquid or the drying liquid from the drain line to the recovery line.

12. A substrate processing method comprising:
providing the substrate processing apparatus according to claim 2;
controlling the second supply to start a supply of the rinse liquid or the drying liquid to the substrate, in a first state where the first processing cup receives a liquid;
after a predetermined time elapses from a start of the supply of the rinse liquid or the drying liquid, controlling a cup switch that switches between the first state and a second state where the second processing cup receives a liquid, to switch from the first state to a second state;
measuring the purity of the rinse liquid or the drying liquid by using the first gauge, in the second state;
determining whether the rinse liquid or the drying liquid is recoverable based on the purity of the rinse liquid or the drying liquid measured in the measuring; and
when determined that the rinse liquid or the drying liquid is recoverable, controlling the line switch to switch an inflow destination of the rinse liquid or the drying liquid from the drain line to the recovery line.

13. A substrate processing method comprising:
providing the substrate processing apparatus according to claim 3;
supplying the rinse liquid or the drying liquid to the substrate from the second supply, in a first state where the first processing cup receives a liquid;
measuring the purity of the rinse liquid or the drying liquid by using the second gauge in the supplying;
determining whether the rinse liquid or the drying liquid is recoverable based on the purity of the rinse liquid or the drying liquid measured in the measuring; and
when determined that the rinse liquid or the drying liquid is recoverable, controlling a cup switch that switches between the first state and a second state where the second processing cup receives a liquid, to switch from the first state to the second state.

14. A substrate processing method comprising:
regenerating the rinse liquid recovered from the substrate processing apparatus according to claim 1; and
generating a new rinse liquid from a regenerated rinse liquid obtained in the regenerating, and supplying the new rinse liquid generated in the generating to the second supply of the substrate processing apparatus.

15. A supply method comprising:
providing the supply system according to claim 9;
measuring the purity of the regenerated rinse liquid flowing in the circulation line, by using the third gauge;
when the purity of the regenerated rinse liquid measured in the measuring is equal to or more than a threshold value, controlling the second supply to eject the regenerated rinse liquid from the second nozzle; and
when the purity of the regenerated rinse liquid measured in the measuring is less than the threshold value, controlling a discharge block that discharges the regenerated rinse liquid from the storage, to discharge the regenerated rinse liquid stored in the storage, and controlling the second supply to eject a fresh liquid of the rinse liquid from the second nozzle.
